(19) United States
(12) Patent Application Publication
(10) Pub. No.: US 2025/0266847 A1
(43) Pub. Date: Aug. 21, 2025

(54) CODING OF SIGNAL IN FREQUENCY BANDS

(71) Applicant: InterDigital CE Patent Holdings, SAS, Paris (FR)

(72) Inventors: Philippe Guillotel, Vern sur Seiche (FR); Quentin Galvane, Thorigne-Fouillard (FR); Fabien Danieau, Rennes (FR); Jean-Maxime Le Carpentier, Orvault (FR)

(21) Appl. No.: 18/856,287

(22) PCT Filed: Mar. 28, 2023
(86) PCT No.: PCT/EP2023/058012

§ 371 Date: Oct. 11, 2024

(30) Foreign Application Priority Data
Apr. 14, 2022 (EP) 22305551.8

(51) Int. Cl. H03M 7/30

(52) U.S. Cl. CPC H03M 7/6011

(57) ABSTRACT

An encoding method and apparatus proposes to encode an input signal based on multiple frequency bands. After decomposing the input signal in multiple frequency bands, a low frequency band signal is encoded based on extracted keyframes comprising temporal references. A residual error signal is generated by subtracting a reconstructed version of the low frequency band signal from the original low frequency band signal. In one embodiment, this residual error signal is then added to one of the frequency bands and encoded with this frequency band. In another embodiment, the residual error signal is encoded separately, as an additional frequency band or separately within an existing band.

### TECHNICAL FIELD

At least one of the present embodiments generally relates to signal encoding and more particularly to a method and device for accurately coding a haptic signal in frequency bands.

### BACKGROUND

Fully immersive user experiences are proposed to users through immersive systems based on feedback and interactions. The interaction may use conventional ways of control that fulfill the need of the users. Current visual and auditory feedback provide satisfying levels of realistic immersion. Additional feedback can be provided by haptic effects that allow a human user to perceive a virtual environment with his senses and thus get a better experience of the full immersion with improved realism. However, haptics is still one area of potential progress to improve the overall user experience in an immersive system.

Conventionally, an immersive system may comprise a 3D scene representing a virtual environment with virtual objects localized within the 3D scene. To improve the user interaction with the elements of the virtual environment, haptic feedback may be used through stimulation of haptic actuators. Such interaction is based on the notion of “haptic objects” that correspond to physical phenomena to be transmitted to the user. In the context of an immersive scene, a haptic object allows to provide a haptic effect by defining the stimulation of appropriate haptic actuators to mimic the physical phenomenon on the haptic rendering device. Different types of haptic actuators allow to restitute different types of haptic feedbacks.

An example of a haptic object is an explosion. An explosion can be rendered though vibrations and heat, thus combining different haptic effects on the user to improve the realism. An immersive scene typically comprises multiple haptic objects, for example using a first haptic object related to a global effect and a second haptic object related to a local effect.

The principles described herein apply to any immersive environment using haptics such as augmented reality, virtual reality, mixed reality, or haptics-enhanced video (or omnidirectional/360° video) rendering, for example, and more generally apply to any haptics-based user experience. A scene for such examples of immersive environments is thus considered an immersive scene.

Haptics refers to sense of touch and includes two dimensions, tactile and kinesthetic. The first one relates to tactile sensations such as friction, roughness, hardness, temperature and is felt through the mechanoreceptors of the skin (Merkel cell, Ruffini ending, Meissner corpuscle, Pacinian corpuscle). The second one is linked to the sensation of force/torque, position, motion/velocity provided by the muscles, tendons and the mechanoreceptors in the joints. Haptics is also involved in the perception of self-motion since it contributes to the proprioceptive system (i.e., perception of one's own body). Thus, the perception of acceleration, speed or any body model could be assimilated as a haptic effect. The frequency range is about 0-1 KHz depending on the type of modality. Most existing devices able to render haptic signals generate vibrations. Examples of such haptic actuators are linear resonant actuator (LRA), eccentric rotating mass (ERM), and voice-coil linear motor. These actuators may be integrated into haptic rendering devices such as haptic suits but also smartphones or game controllers.

To encode haptic signals, several formats have been defined related to either a high-level description using XML-like formats (for example MPEG-V), parametric representation using json-like formats such as Apple Haptic Audio Pattern (AHAP) or Immersion Corporation's HAPT format, or waveform encoding (IEEE 1918.1.1 ongoing standardization for tactile and kinesthetic signals). The HAPT format has been recently included into the MPEG ISOBMFF file format specification (ISO/IEC 14496 part 12). Moreover, GL Transmission Format (glTF™) is a royalty-free specification for the efficient transmission and loading of 3D scenes and models by applications. This format defines an extensible, common publishing format for 3D content tools and services that streamlines authoring workflows and enables interoperable use of content across the industry.

Moreover, a new haptic file format is being defined within the MPEG standardization group and relates to a coded representation for haptics. The Reference Model of this format is not yet released but is referenced herein as RM0. With this reference model, the encoded haptic description file can be exported either as a JSON interchange format (for example a .gmpg file) that is human readable or as a compressed binary distribution format (for example a .mpg) that is particularly adapted for transmission towards haptic rendering devices.

### SUMMARY

Embodiments are related the encoding of an input signal (for example a haptic signal) based on multiple frequency bands. The input signal is decomposed in multiple frequency bands. The low frequency band signal is encoded based on extracted keyframes comprising temporal references. A residual error signal is generated by subtracting a reconstructed version of the low frequency band signal to the original low frequency band signal. In one embodiment, this residual error signal is then added to one of the frequency bands and encoded with this frequency band. In another embodiment, the residual error signal is encoded separately, as an additional frequency band or in an existing frequency but encoded separately.

A first aspect of at least one embodiment is directed to a method comprising decomposing an input signal into frequency bands comprising a low frequency band signal and a high frequency band signal, encoding data extracted from the low frequency band signal, reconstructing a signal from the encoded data using a decoding method inverse to the encoding, determining a residual signal by subtracting the reconstructed signal from the low frequency band signal, adding the residual signal to the high frequency band signal, encoding data extracted from the high frequency band signal and providing the encoded data for low frequency band and the high frequency band.

A second aspect of at least one embodiment is directed to a method comprising decomposing an input signal into frequency bands comprising a low frequency band signal and a high frequency band signal, encoding data extracted from the low frequency band signal, reconstructing a signal from the encoded data using a decoding method inverse to the encoding, determining a residual signal by subtracting the reconstructed signal from the low frequency band signal, encoding data extracted from the residual band signal, encoding data extracted from the high frequency band signal, and providing the encoded data for the low frequency band signal, the residual band signal, and the high frequency band signal.

A third aspect of at least one embodiment is directed to a method comprising decomposing an input signal into frequency bands comprising a low frequency band signal, encoding data extracted from the low frequency band signal, reconstructing a signal from the encoded data using a decoding method inverse to the encoding, determining a residual signal by subtracting the reconstructed signal from the low frequency band signal, encoding data extracted from the residual band signal, and providing the encoded data for the low frequency band signal and the residual band signal.

A fourth aspect of at least one embodiment is directed to a device comprising a processor configured to decompose an input signal into frequency bands comprising a low frequency band signal and a high frequency band signal, encode data extracted from the low frequency band signal, reconstruct a signal from the encoded data using a decoding method inverse to the encoding, determine a residual signal by subtracting the reconstructed signal from the low frequency band signal, add the residual signal to the high frequency band signal, encode data extracted from the high frequency band signal and provide the encoded data for low frequency band and the high frequency band.

A fifth aspect of at least one embodiment is directed to a device comprising a processor configured to decompose an input signal into frequency bands comprising a low frequency band signal, encode data extracted from the low frequency band signal, reconstruct a signal from the encoded data using a decoding method inverse to the encoding, determine a residual signal by subtracting the reconstructed signal from the low frequency band signal, encode data extracted from the residual band signal, and provide the encoded data for the low frequency band signal and the residual band signal.

A sixth aspect of at least one embodiment is directed to a device comprising a processor configured to decompose an input signal into frequency bands comprising a low frequency band signal, encode data extracted from the low frequency band signal, reconstruct a signal from the encoded data using a decoding method inverse to the encoding, determine a residual signal by subtracting the reconstructed signal from the low frequency band signal, encode data extracted from the residual band signal, and provide the encoded data for the low frequency band signal and the residual band signal.

A seventh aspect of at least one embodiment is directed to a computer program comprising program code instructions executable by a processor, the computer program implementing at least the steps of a method according to the first, second or third aspect.

An eighth aspect of at least one embodiment is directed to a computer program product stored on a non-transitory computer readable medium and comprising program code instructions executable by a processor, the computer program product implementing at least the steps of a method according to the first, second or third aspect.

### BRIEF DESCRIPTION OF THE DRAWINGS

FIG. 1 illustrates a block diagram of an example of a system in which various aspects and embodiments are implemented.

FIG. 2 illustrates an example of structure for describing an immersive scene according to one embodiment.

FIG. 3 illustrates an example of structure for the interchange file format describing an immersive scene.

FIG. 4 illustrates an example of signal coded using two haptic bands.

FIG. 5 illustrates the conventional method for encoding a low-level haptic signal in two bands of frequencies.

FIG. 6A to 6F illustrates the differences induced by the keyframe interpolation on an example of input signal.

FIG. 7 illustrates a method for encoding a low-level haptic signal in two bands of frequencies according to a first embodiment.

FIG. 8 illustrates a method for decoding a low-level haptic signal in two bands of frequencies according to the first embodiment.

FIG. 9 illustrates a method for encoding a low-level haptic signal in two bands of frequencies according to a second embodiment.

FIG. 10 illustrates a method for decoding a low-level haptic signal in three bands of frequencies according to the first variant of the second embodiment.

### DETAILED DESCRIPTION

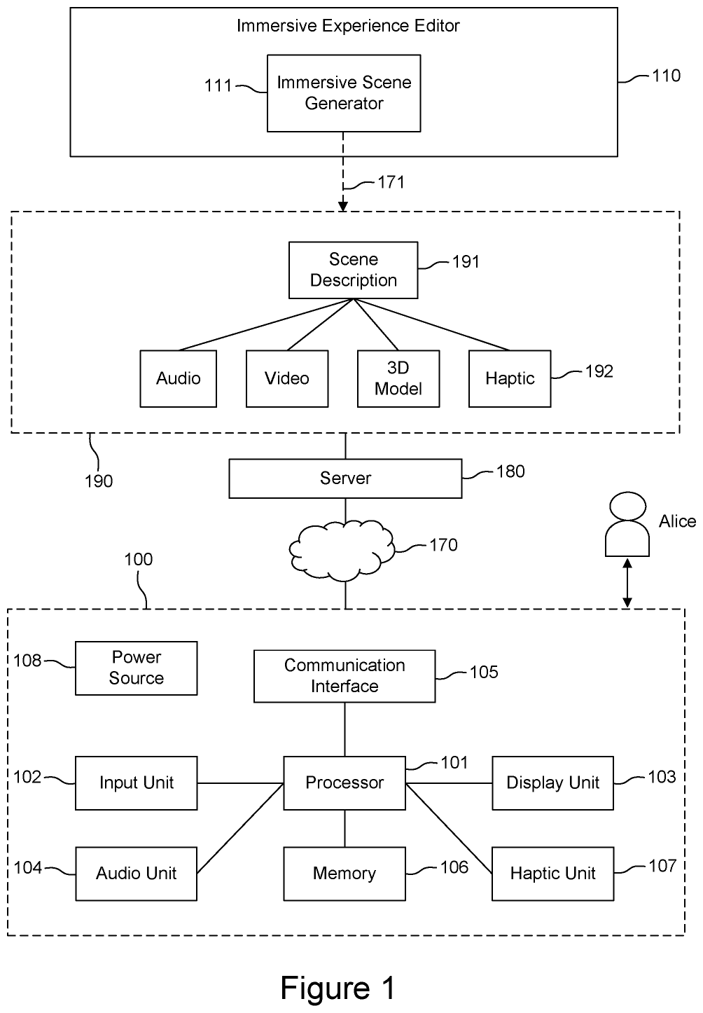

FIG. 1 illustrates a block diagram of an example of immersive system in which various aspects and embodiments are implemented. In the depicted immersive system, the user Alice uses the haptic rendering device 100 to interact with a server 180 hosting an immersive scene 190 through a communication network 170. This immersive scene 190 may comprise various data and/or files representing different elements (scene description 191, audio data, video data, 3D models, and haptic description file 192) required for its rendering. The immersive scene 190 may be generated under control of an immersive experience editor 110 that allows to arrange the different elements together and design an immersive experience. Appropriate description files and various data files representing the immersive experience are generated by an immersive scene generator 111 (i.e., an encoder) and encoded in a format adapted for transmission to haptic rendering devices. The immersive experience editor 110 is typically performed on a computer that will generate immersive scene to be hosted on the server. For the sake of simplicity, the immersive experience editor 110 is illustrated as being directly connected through the dotted line 171 to the immersive scene 190. In practice, the immersive scene 190 is hosted on the server 180 and the computer running the immersive experience editor 110 is connected to the server 180 through the communication network 170.

The haptic rendering device 100 comprises a processor 101. The processor 101 may be a general-purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit (IC), a state machine, and the like. The processor may perform data processing such as haptic signal decoding, input/output processing, and/or any other functionality that enables the device to operate in an immersive system.

The processor 101 may be coupled to an input unit 102 configured to convey user interactions. Multiple types of inputs and modalities can be used for that purpose. Physical keypad or a touch sensitive surface are typical examples of input adapted to this usage although voice control could also be used. In addition, the input unit may also comprise a digital camera able to capture still pictures or video in two dimensions or a more complex sensor able to determine the depth information in addition to the picture or video and thus able to capture a complete 3D representation. The processor 101 may be coupled to a display unit 103 configured to output visual data to be displayed on a screen. Multiple types of displays can be used for that purpose such as a liquid crystal display (LCD) or organic light-emitting diode (OLED) display unit. The processor 101 may also be coupled to an audio unit 104 configured to render sound data to be converted into audio waves through an adapted transducer such as a loudspeaker for example. The processor 101 may be coupled to a communication interface 105 configured to exchange data with external devices. The communication preferably uses a wireless communication standard to provide mobility of the haptic rendering device, such as cellular (e.g., LTE) communications, Wi-Fi communications, and the like. The processor 101 may access information from, and store data in, the memory 106, that may comprise multiple types of memory including random access memory (RAM), read-only memory (ROM), a hard disk, a subscriber identity module (SIM) card, a memory stick, a secure digital (SD) memory card, any other type of memory storage device. In embodiments, the processor 101 may access information from, and store data in, memory that is not physically located on the device, such as on a server, a home computer, or another device.

The processor 101 is coupled to a haptic unit 107 configured to provide haptic feedback to the user, the haptic feedback being described in the haptic description file 192 that is related to the scene description 191 of an immersive scene 190. The haptic description file 192 describes the kind of feedback to be provided according to the syntax described further hereinafter. Such description file is typically conveyed from the server 180 to the haptic rendering device 100. The haptic unit 107 may comprise a single haptic actuator or a plurality of haptic actuators located at a plurality of positions on the haptic rendering device. Different haptic units may have a different number of actuators and/or the actuators may be positioned differently on the haptic rendering device.

In at least one embodiment, the processor 101 is configured to render a haptic signal according to embodiments described further below, in other words to apply a low-level signal to a haptic actuator to render the haptic effect. Such low-level signal may be represented using different forms, for example by metadata or parameters in the description file or by using a digital encoding of a sampled analog signal (e.g., PCM or LPCM).

The processor 101 may receive power from the power source 108 and may be configured to distribute and/or control the power to the other components in the device 100. The power source may be any suitable device for powering the device. As examples, the power source may include one or more dry cell batteries (e.g., nickel-cadmium (NiCd), nickel-zinc (NiZn), nickel metal hydride (NiMH), lithium-ion (Li-ion), and the like), solar cells, fuel cells, and the like.

While the figure depicts the processor 101 and the other elements 102 to 108 as separate components, it will be appreciated that these elements may be integrated together in an electronic package or chip. It will be appreciated that the haptic rendering device 100 may include any sub-combination of the elements described herein while remaining consistent with an embodiment. The processor 101 may further be coupled to other peripherals or units not depicted in FIG. 1 which may include one or more software and/or hardware modules that provide additional features, functionality and/or wired or wireless connectivity. For example, the peripherals may include sensors such as a universal serial bus (USB) port, a vibration device, a television transceiver, a hands-free headset, a Bluetooth® module, a frequency modulated (FM) radio unit, a digital music player, a media player, a video game player module, an Internet browser, and the like. For example, the processor 101 may be coupled to a localization unit configured to localize the haptic rendering device within its environment. The localization unit may integrate a GPS chipset providing longitude and latitude position regarding the current location of the haptic rendering device but also other motion sensors such as an accelerometer and/or an e-compass that provide localization services.

Typical examples of haptic rendering device 100 are haptic suits, smartphones, game controllers, haptic gloves, haptic chairs, haptic props, motion platforms, etc. However, any device or composition of devices that provides similar functionalities can be used as haptic rendering device 100 while still conforming with the principles of the disclosure.

In at least one embodiment, the device does not include a display unit but includes a haptic unit. In such embodiment, the device does not render the scene visually but only renders haptic effects. However, the device may prepare data for display so that another device, such as a screen, can perform the display. Example of such devices are haptic suits or motion platforms.

In at least one embodiment, the device does not include a haptic unit but includes a display unit. In such embodiment, the device does not render the haptic effect but only renders the scene visually. However, the device may prepare data for rendering the haptic effect so that another device, such as a haptic prop, can perform the haptic rendering. Examples of such devices are smartphones, head-mounted displays, or laptops.

In at least one embodiment, the device does not include a display unit nor does it include a haptic unit. In such embodiment, the device does not visually render the scene and does not render the haptic effects. However, the device may prepare data for display so that another device, such as a screen, can perform the display and may prepare data for rendering the haptic effect so that another device, such as a haptic prop, can perform the haptic rendering. Examples of such devices are computers, game consoles, optical media players, or set-top boxes.

In at least one embodiment, the immersive scene 190 and associated elements are directly hosted in memory 106 of the haptic rendering device 100 allowing local rendering and interactions. In a variant of this embodiment, the device 100 also comprises the immersive experience editor 110 allowing a fully standalone operation, for example without needing any communication network 170 and server 180.

Although the different elements of the immersive scene 190 are depicted in FIG. 1 as separate elements, the principles described herein apply also in the case where these elements are directly integrated in the scene description and not separate elements. Any mix between two alternatives is also possible, with some of the elements integrated in the scene description and other elements being separate files.

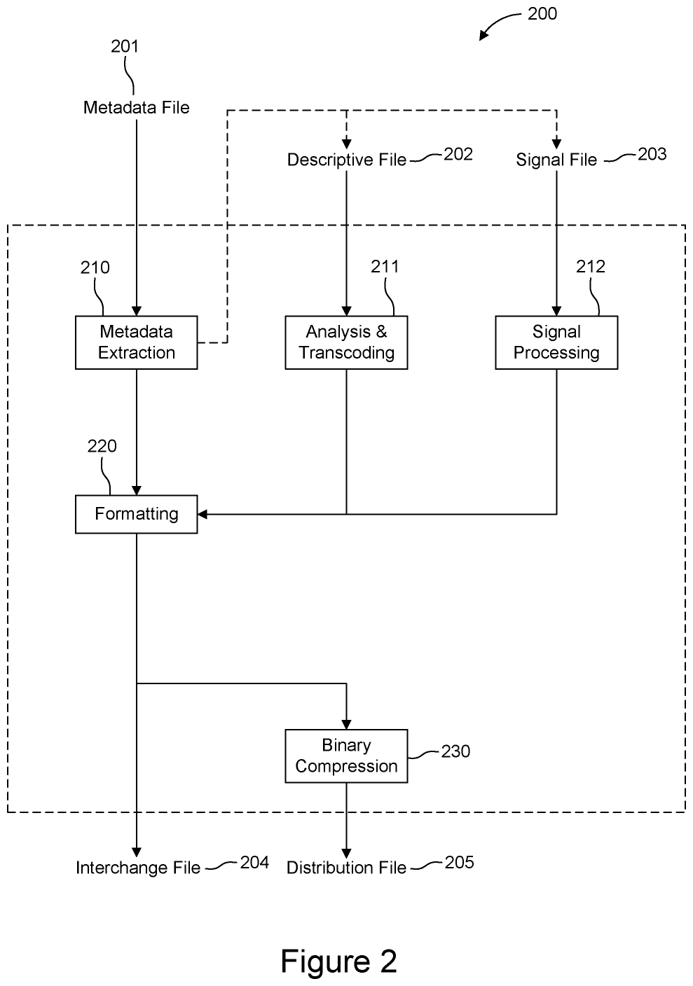

FIG. 2 illustrates an example of process for encoding an immersive description file. This encoding process 200 is for example implemented as a module of immersive scene generator 111 of an immersive editor 110 and typically performed on a computer generating the files describing the immersive scene. It may also be implemented on a computer, or a specific hardware platform dedicated to encoding immersive description files. The inputs are a metadata file 201 and at least one low-level haptic signal file 203. The metadata file 201 is for example based on the ‘OHM’ haptic object file format. The signal files are representing analog signals to be applied to haptic actuators and are conventionally encoded using a pulse coded modulation (PCM) for example based on the WAV file format. The descriptive files 202 are for example based on the AHAP or HAPT file formats.

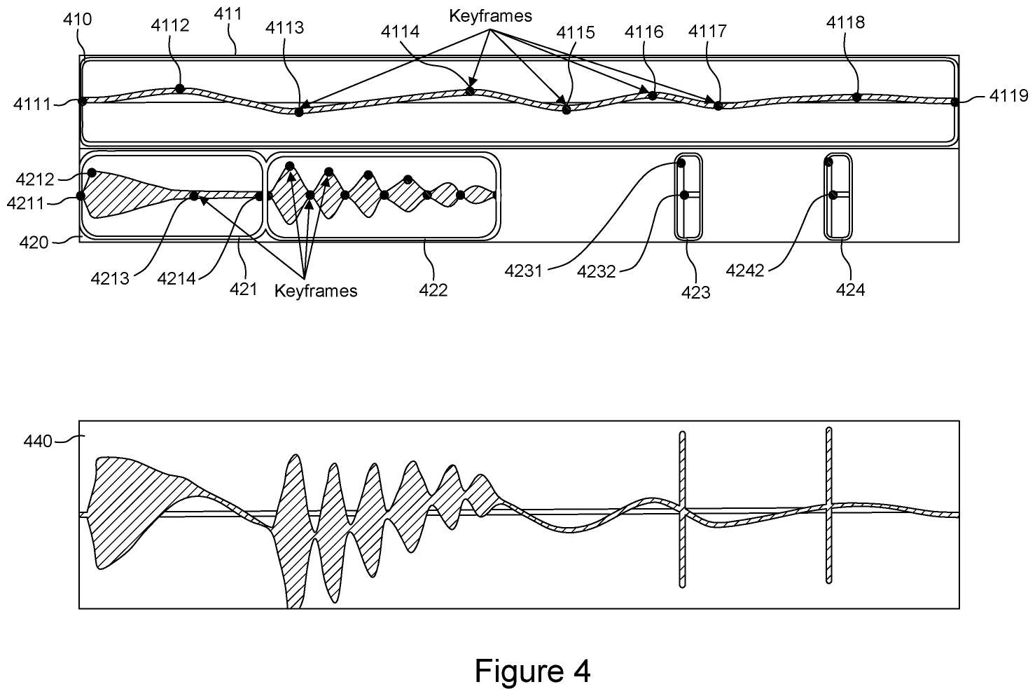

Metadata is extracted in step 210 from the metadata file 201, allowing to identify the descriptive files and/or signal files. Descriptive files are analyzed and transcoded in step 211. In step 212, signal files are processed. This step 212 comprises decomposing the signal in frequency bands and keyframes or wavelets, as further described in FIG. 4.

The interchange file 204 is then generated in step 220, in compliance with the data format according to one of the embodiments described herein. The interchange file 204 may be compressed in step 230 to be distributed in a transmission-friendly form such as the distribution file 205, more compact than the interchange file format.

The interchange file 204 can be a human readable file for example based on glTF, XML or JSON formats. The distribution file 205 is a binary encoded file for example based on MPEG file formats adapted for streaming or broadcasting to a decoder device.

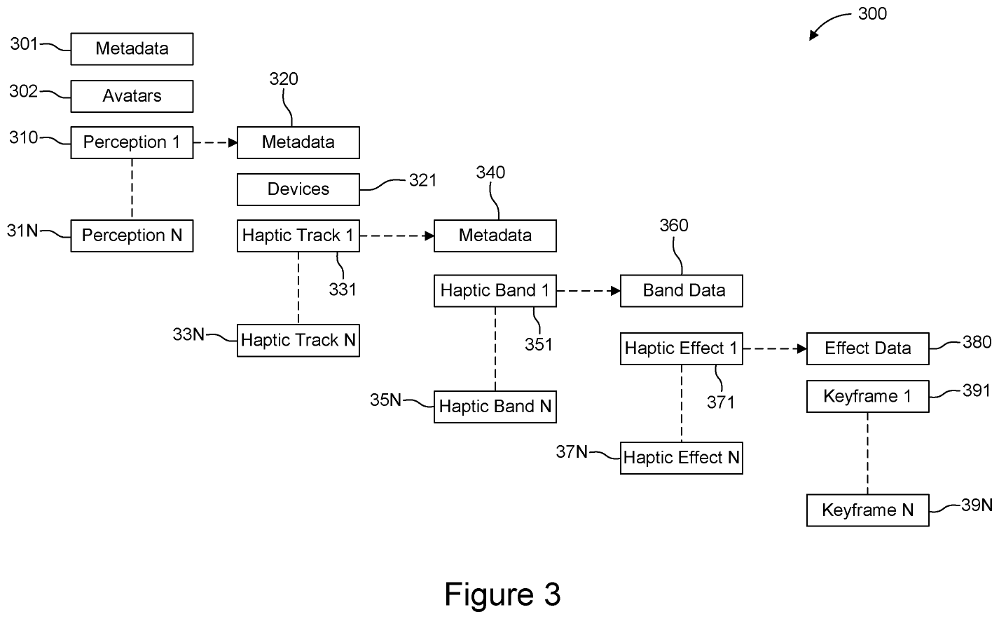

FIG. 3 illustrates an example of structure for the interchange file format describing an immersive scene. The data structure 300 represents the immersive scene 190. It can be decomposed in a set of layers. At the upper layer, metadata 301 describe high-level metadata information regarding the overall haptic experience defined in the data structure 300 and a list of avatars (i.e., body representation) later referenced in the file. These avatars allow to specify a target location of haptic stimuli on the body. The haptic effects are described through a list of perceptions 310, 31N. These perceptions correspond to haptic signals associated with specific perception modalities such as vibration, force, position, velocity, temperature, etc.). A perception comprises metadata 320 to describe the haptic content of the signal, devices 321 to describe specifications of the haptic devices for which the signal was designed and a list of haptic tracks 331, 33N. A haptic track comprises metadata 340) to describe the content of the track, the associated gain value, a mixing weight, body localization information and a reference to haptic device specification (defined at the perception level). The track finally contains a list of haptic bands 351, 35N, each band defining a subset of the signal within a given frequency range. For example, the haptic band 351 may correspond to the range of frequencies from 0 to 50 Hz while the haptic band 35N may correspond to the range of frequencies over 2 kHz. A haptic band comprises band data 360 to describe the frequency range of the band, the type of encoding modality (Vectorial or Wavelet), the type of band (Transient, Curve and Wave) and optionally the type of curve (Cubic, Linear or unknown) or the window length. A haptic band is defined by a list of haptic effects 371, 37N. Finally, a haptic effect comprises a list of keyframes 391, 39N and effect data 380, a keyframe being defined by a position (i.e., a temporal reference), a frequency and an amplitude. The effect data describes the type of base signal selected amongst Sine, Square, Triangle, Saw ToothUp, and Saw ToothDown as well as provide temporal references such as timestamps. The low-level haptic signal can then be reconstructed by combining the keyframes of the haptic effects in the different bands, as illustrated in the example of FIG. 3.

FIG. 4 illustrates an example of signal coded using two haptic bands. With this technique, a low-level haptic signal is encoded using a two frequency bands, a low frequency band 410 and a high frequency band 420, each of them defining a part of the signal in a given frequency range. In this example, the low frequency band corresponds to frequencies below 72.5 Hz Hz while the high frequency band corresponds to frequencies equal to or higher than 72.5 Hz. On the rendering side, the device combines the two parts together (i.e., adding them together) to generate the final haptic signal 440.

The data for a frequency band may be reconstructed based on keyframes and according to a type of haptic band selected amongst Transient, Curve and Wave bands. Additionally, for

Wave bands, two types of encoding modalities can be used: Vectorial or Wavelet. Each band is composed of a series of Effects and each Effect is defined by a list of Keyframes that are represented as dots in the figure. The data contained in the effects and keyframes is interpreted differently for different types of haptic bands and encoding modalities.

For a Transient band, each effect stores a set of keyframes defining a position, an amplitude, and a frequency. A keyframe represents a transient event. The signal may be reconstructed using the type of periodic base signal specified in the effect metadata with the amplitude specified in the key frame and the period given by the frequency of the key frame. A transient event is a very short signal generated for a few periods only. The number of generated periods is determined by the decoder.

For a Curve band, each effect stores a set of keyframes defining a position (i.e., a temporal reference) and an amplitude. The keyframes represent control points of a curve and an interpolation is performed to generate the curve from the control points. The type of interpolation function is either cubic or linear and is specified in the metadata of the band (380 in FIG. 3). The signal may be reconstructed by performing an interpolation between the amplitudes of keyframes according to their temporal references.

For Vectorial Wave bands, the effect stores a set of keyframes defining a position (i.e., a temporal reference), an amplitude and a frequency. In this case, the signal is generated using the type of periodic base signal specified in the effect metadata with the amplitude specified in the keyframe and the period given by the frequency of the keyframe. The SPIHT wavelet encoding scheme (http://www siliconimaging.com/SPIHT.htm) may be used for the Wavelet band or types of wavelet encoding. For example, for the Wavelet band, the effect may store the contents of one wavelet block. It contains a keyframe for every coefficient of the wavelet transformed and quantized signal, indicating the amplitude value of the wavelet. The coefficients are scaled to a range of [−1, 1]. Additionally, the original maximum amplitude is stored in a keyframe, as well as the maximum number of used bits. In this case, the signal may be reconstructed using the coefficients to perform an inverse wavelet transform.

The frequency band decomposition may use a Low Pass Filter and a High pass filter to split the signal into a low frequency band and a high frequency band. The two bands are then processed differently. Various methods can be used for the encoding of the high frequency part. A first solution is to split the high frequency signal into smaller fixed length windows and use Short-time Fourier Transform (STFT) to decompose the signal in the frequency spectrum. Another solution is to use wavelet transforms to encode the high frequencies. The data structure illustrated in FIG. 3 allows to define multiple bands with different frequency ranges. These bands are used to store the coefficients of the Fourier or Wavelet Transforms.

For the low frequency part of the signal, the data of this frequency band is stored through a list of keyframe points defined by a timestamp and an amplitude. The data also contains information relative to the type of interpolation used to reproduce the signal of this band. The keyframes (i.e., control points) defining the low frequency band are obtained by simply extracting the local extrema of the low frequency signal.

In the example of the figure, the low frequency band 410 is defined as a Curve band using a single effect 411. Such representation is particularly adapted to the low frequency part of the signal. The effect 411 is defined by the keyframes 4111, 4112, 4113, 4114, 4115, 4116, 4117, 4118, 4119. The signal for the low frequency band is generated by a cubic interpolation between these keyframes. The high frequency band 420 is defined by 4 effects 421, 422, 423, 424. The effect 421 is defined as a Vectorial band defined by 4 keyframes 4211, 4212, 4213, 4214.

While the description is based on a set of two bands defining a range for low frequencies and a range for high frequencies, the principles apply also in the case more than two ranges of frequencies are used. In this case, the low frequency band becomes the lowest frequency band, and the high frequency band becomes the highest frequency band. The lowest frequency band may for example be encoded using a curve band using a single effect, as represented by the low frequency band 410 of FIG. 4. Other frequency bands may be encoded with any of the other type of encoding, for example using a vectorial wave band based on wavelets, as represented by the high frequency band 420 of FIG. 4 but using multiple instances of encoding, one for each band of frequencies.

One advantage of this solution with regards to the structure is that the signal data is easy to package and particularly convenient for streaming purposes Indeed, with such linear structure, the data can be easily broken down to small consecutive packages and does not require complicated data-pre-fetching operations. The signal is easily reconstructed by patching the packages back together to ensure a smooth playback of the signal. It may also be reconstructed by only taking the low frequency part and reconstruct a lower quality (but potentially sufficient) signal without taking into account the high frequency band.

As detailed in the following section, the further sections of this document describe the encoding of PCM waveform signals, for example carried by input WAV files. In this context, an input WAV file describes a single perception modality and even if the file contains multiple tracks, the encoder will process each track separately. Therefore, for the sake of clarity in the remainder of the disclosure, the description will describe the coding of a single track.

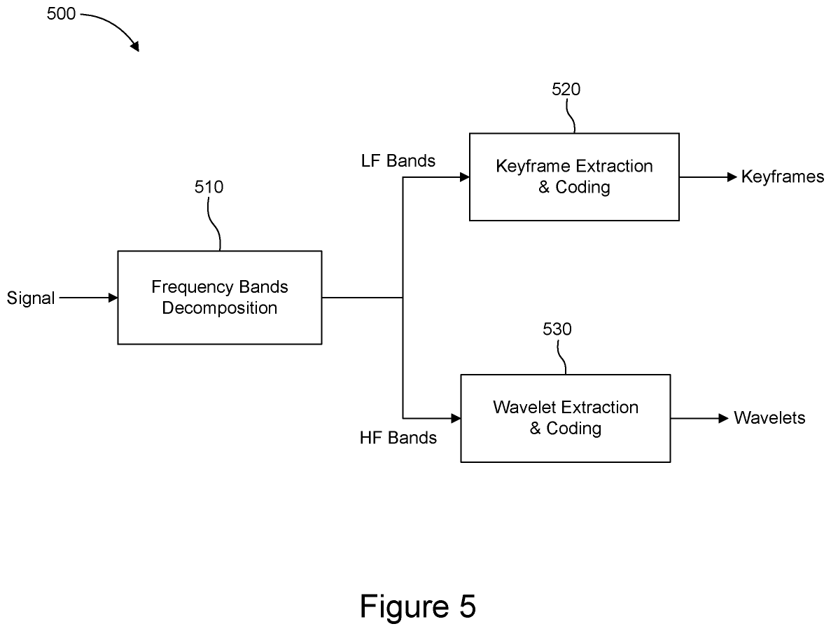

FIG. 5 illustrates the conventional method for encoding a low-level haptic signal in two bands of frequencies. This corresponds to the signal processing step 212 of FIG. 2 and is for example implemented by an encoder such as the immersive scene generator 111 of FIG. 1. Given an input PCM signal, the encoder starts the process 500 by performing a frequency band decomposition. Using a Low Pass Filter and a High pass filter, the encoder splits, in step 510, the signal into a low frequency band and a high frequency band. In step 520, the encoder extracts the keyframes for the low frequency band to be encoded as a Curve band, and in step 530 extracts the wavelets for the high frequency band to be encoded as a Wave band, as described above in FIGS. 4. The keyframes and wavelet extracted data are then formatted according to the structure of FIG. 3 in the formatting step 220 of FIG. 2.

This hybrid format combining Curve bands and Wave bands is interesting and allows to store low frequency signals very easily. This is especially convenient for clean synthetic signals that were produced through Haptic authoring tools (in particular kinesthetic signals). For recorded signals that are usually much noisier and more complex, such encoding of the low frequencies can generate errors in the output signals. Indeed, the interpolation method used to generate signals between the extracted local extrema is limited and often fails to capture the details of the input signal. This may introduce some non-negligible errors.

As a result, the low-level haptic signal that is decoded and used by the haptic rendering device to render the haptic effect may be different from the low-level haptic signal provided to the immersive scene generator 111 that encoded the immersive scene. The difference is induced by the encoding principles.

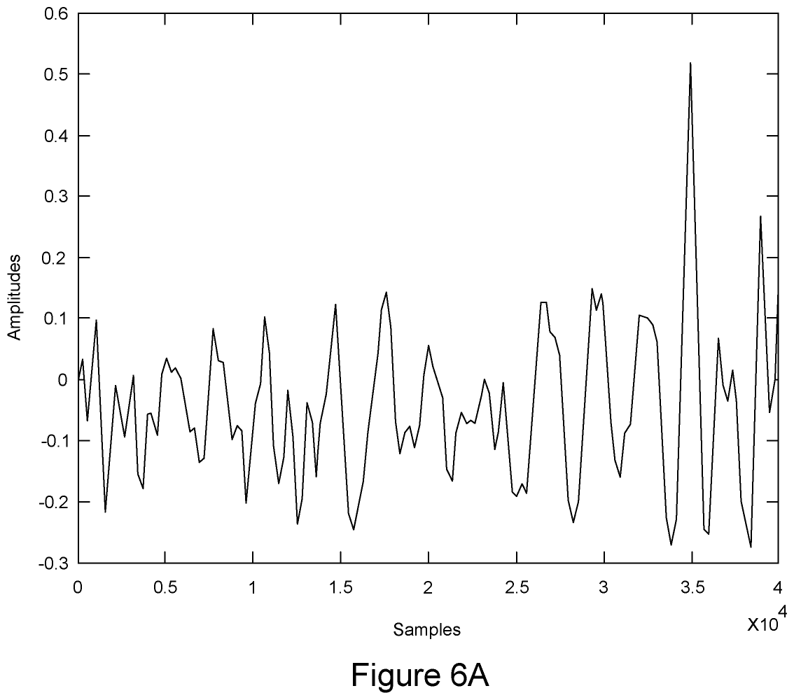

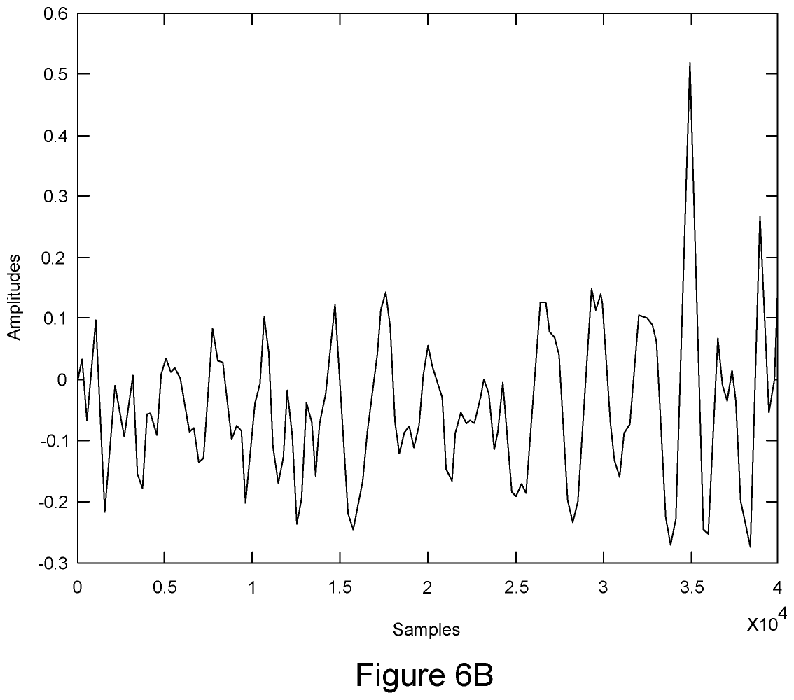

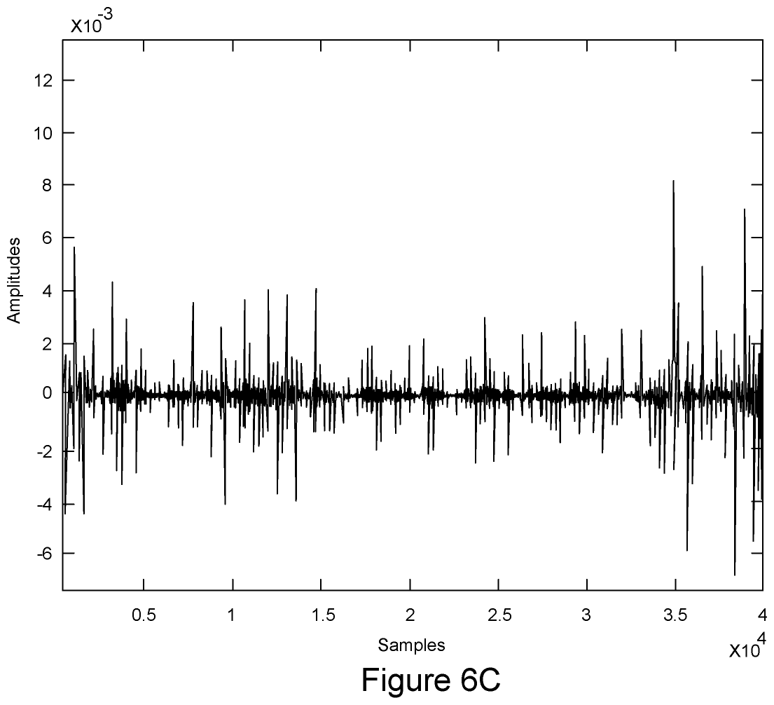

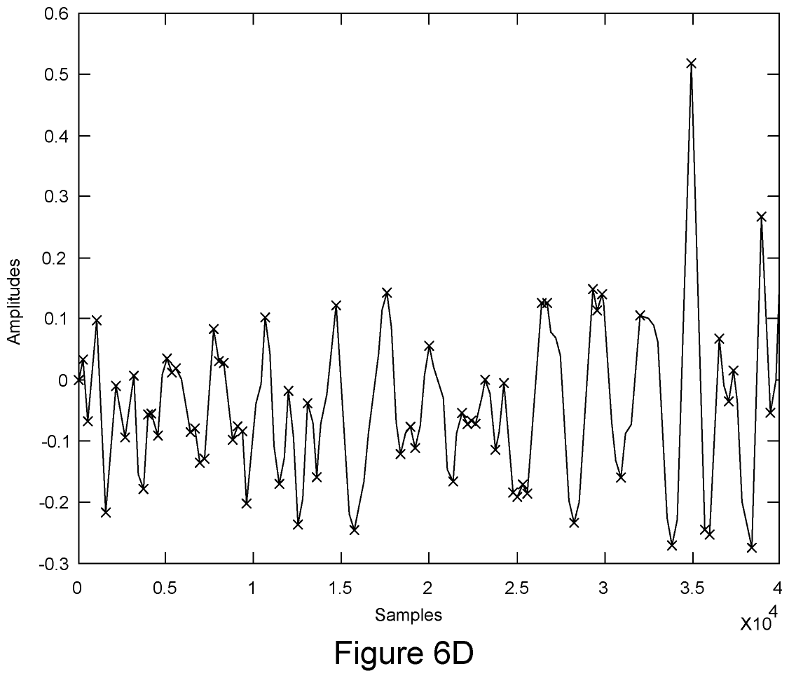

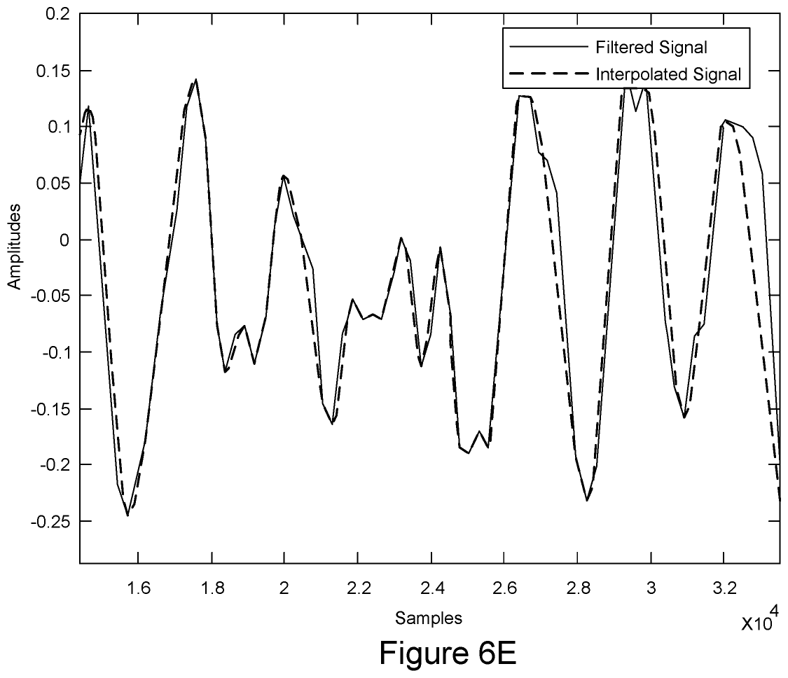

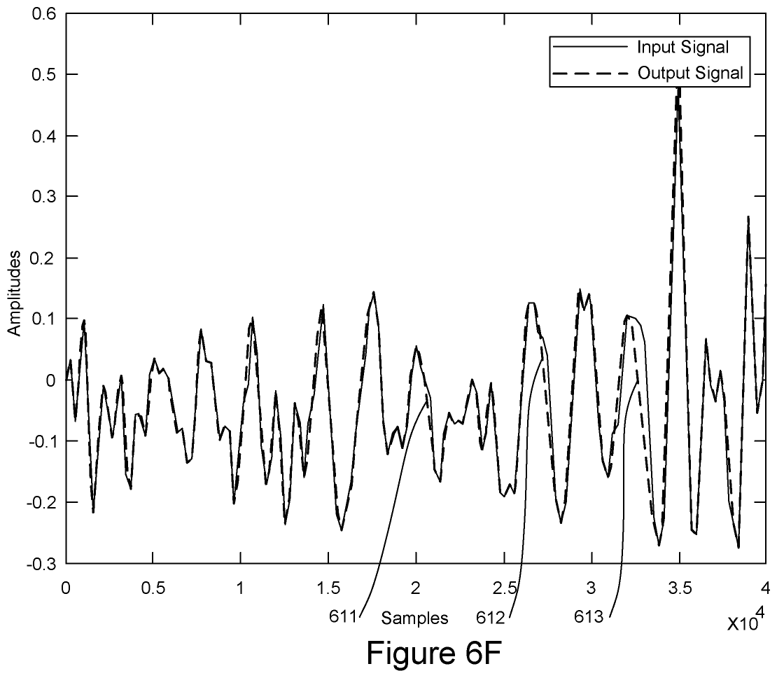

FIG. 6A to 6E illustrates the differences induced by the keyframe interpolation on an example of input signal. FIG. 6A shows the input signal. Unfortunately, the limited resolution of the picture in the document does not allow convey the fine details and especially details of the high frequencies. FIG. 6B and 6C respectively shows the decomposition into the low frequency band and the high frequency band. FIG. 6D shows the result of the analysis of the low frequency band and the identification of the keyframes, herein identified by crosses, corresponding to the extreme values of the curve. These values would then be provided to the decoder, i.e. a haptic rendering device, for decoding along with the type of interpolation to be used, selected between cubic or linear. FIG. 6E illustrates the discrepancies in the reconstruction of the low frequency signal. It shows the low frequency band part of the input signal represented by a dotted line and the low frequency signal as it may be generated using the selected interpolation of the keyframes, represented by the solid line. The figure only shows a subset of the complete signal but with better resolution in order to be able to visualize the difference between the input signal and its reconstructed version, which is clearly visible. FIG. 6F shows the input signal of the encoder, represented by a solid line and the output signal, i.e., the signal reconstructed on the decoder/rendering side, represented as a dotted line, thus comprising both the low and high frequency bands. This figure allows to visualize the differences between the signal intended to be rendered by the haptic rendering and the signal that will be provided to the haptic actuators. It comprises particularly comprises some phase offsets that may hinder the haptic experience since they may not be perfectly synchronized with the haptic scene. For example, the slopes 611, 612, 613 of the reconstructed signal are shifted by the reconstruction so that will be rendered in advance with regards to the input signal and thus temporally out of synchronization with the expected rendering. Although the example of this figure shows small delays, other type of signal may suffer from greater delay. Synchronization between a haptic effect and the corresponding change in the immersive scene are critical to ensure a satisfying user experience. Even a small delay may be noticed by the users. In addition, more severe coding artefacts from higher compression rate or simpler interpolation function (i.e., linear) will result in very bad rendering of the haptic experience.

Embodiments described hereafter have been designed with the foregoing in mind and propose to encode the low-level haptic signal in a more accurate way than the conventional frequency band techniques, thus allowing an improved fidelity of the rendering towards the expected rendering (i.e., the input signal to be encoded). The proposed encoding does not require any modification of the file format or any modification of the haptic rendering device that will receive the immersive scene.

Embodiments propose a new method to accurately encode a signal such as a low-level haptic signal decomposed in a set of frequency bands. Embodiments are based on determining a residual signal corresponding to the difference between the input signal and a reconstructed version of the low frequency band signal and encoding this residual signal in addition to the low frequency and high frequency band signals. A first embodiment proposes to incorporate the residual signal into the high frequency band while a second embodiment proposes to use a residual band to carry the residual signal. Such methods have multiple advantages. The embodiments allow to reduce the discrepancies resulting from the conventional key-frame based low frequency band encoding and thus improves the accuracy of the system by enabling the decoder to render a signal whose fidelity with regards to the original signal is higher than with the conventional encoding. This improvement is done without the need of additional data (except for the second variant of the second embodiment). It is fully compatible with the conventional immersive scene description format described in FIG. 3, with the existing haptic design approaches and with the existing haptic signal rendering methods and devices. In addition, it may adapt to any type of input signal, i.e., it is not limited to haptic signal and may also be applied to audio signals for example.

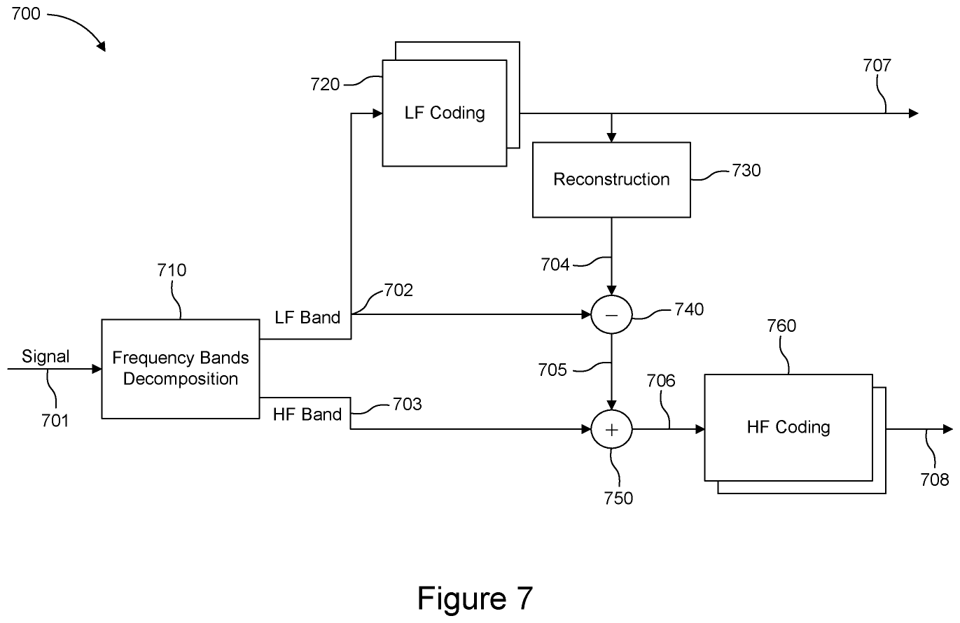

FIG. 7 illustrates a method for encoding a low-level haptic signal in two bands of frequencies according to a first embodiment. Such encoding method corresponds to the signal processing step 212 of FIG. 2 and is for example implemented by an encoder such as the immersive scene generator 111 of FIG. 1. This first method 700 proposes to determine a residual signal corresponding to the difference (i.e., error) between the input signal and a reconstructed version of the low frequency band signal and encode this residual signal with the high frequency band by adding it to the high frequency band signal. In such embodiment, there is no need to use additional transmission channel to carry the data representing the residual error. Indeed, the information corresponding to the residual error is included into the data representing the high frequency band.

The first method 700 for encoding a low-level haptic signal in two bands of frequencies is for example implemented by an encoder such as the immersive scene generator 111 of FIG. 1. In step 710, the encoder splits the input signal 701 into a low frequency band signal 702 and a high frequency band signal 703 as described above. In step 720, the encoder encodes the low frequency band signal 702 according to one of the signal encoding techniques described above and generates data 707 allowing to reconstruct, in step 730, the low frequency band as described above. The data 707 is then used to determine a reconstructed low frequency band signal 704 using the same technique as available in the decoder on the rendering side. This reconstructed signal 704 is then, in step 740, subtracted from the low frequency band signal 702 to determine a low frequency band error signal 705 (a.k.a residual signal) that, in step 750, is added to the high frequency band signal 703 to generate the signal 706. Then, in step 760, the encoder encodes the signal 706 and generates data 708 representing the high frequency band signal. As a result, the data 708 carries not only the part of the signal corresponding to the high frequency band but also the residual signal. The data 707 and 708 are then packaged as described above, for example formatted according to the data structure described in FIG. 3 thus allowing to provide these data to a decoder or a haptic rendering device, using either the human-readable interchange file format or a more compact binary format.

In a variant of the first embodiment, the low frequency band encoding is based on a Curve band encoding so that the step 720 comprises the extraction of keyframes as described above. Any other type of encoding such as the ones described above, or any encoding adapted to a low frequency signal may be used in other variants.

In a variant of the first embodiment, the high frequency band encoding is based on a Vectorial Wave band encoding so that the step 760 comprises the extraction of wavelets as described above. Any other type of encoding such as the ones described above, or any encoding adapted to a high frequency signal may be used in other variants.

This embodiment has been described here in the context of a decomposition in two frequency bands but is still valid in a context where more than two frequency bands are used. Indeed, multiple low frequency bands and/or multiple high frequency bands may be used, thus needing a plurality of coding stages 720 and 760 for the different frequency bands but still based on the same principle of injecting the residuals of the reconstruction of low frequency bands into the high frequency bands.

Advantageously, by using the technique proposed by the first embodiment, there is no need to provide this information to the decoder, even in the case where multiple low and high frequencies bands are used for the encoding.

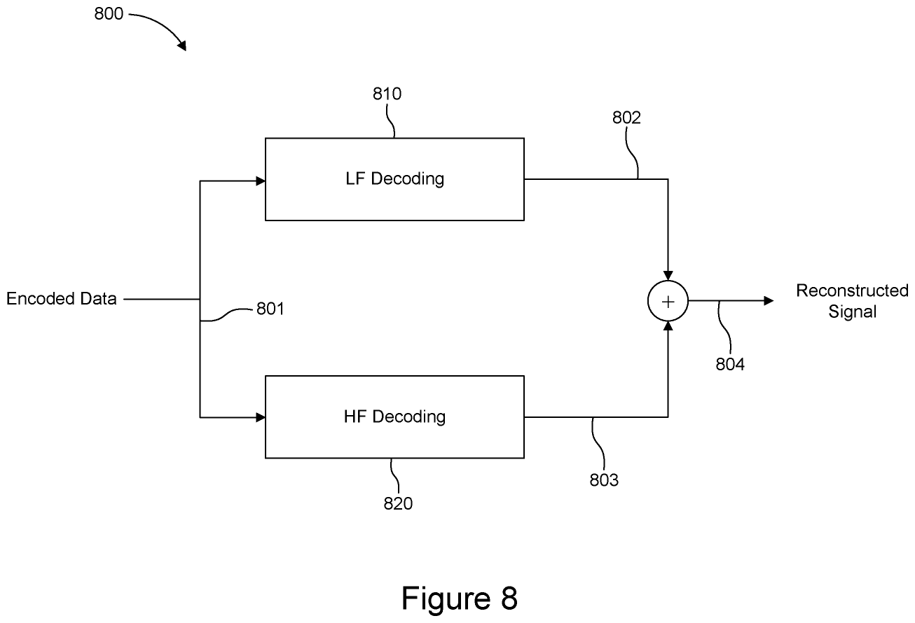

FIG. 8 illustrates a method for decoding a low-level haptic signal in two bands of frequencies according to the first embodiment. This method is for example implemented in a haptic rendering device 100 of FIG. 1 and typically executed by the processor 101 of such device. The processor receives encoded data 801 generated according to FIG. 7, for example formatted according to the data structure described in FIG. 3. In step 810, the decoder reconstructs the signal 802 corresponding to the low frequency band signal. In step 820, the processor reconstructs the signal 803 corresponding to the high frequency band signal. By adding these the signals 802 and 803 together, the processor will therefore compensate the coding errors of the low frequency band thanks to the residual error signal that is comprised in the high frequency band signal and generates a low-level haptic signal that is more accurate to the original signal than with conventional encoding.

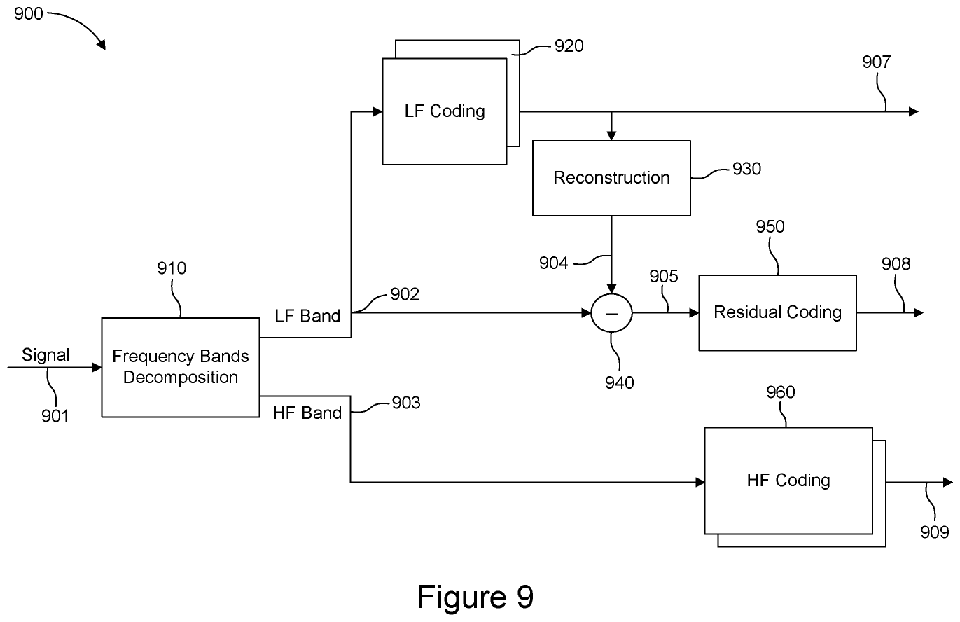

FIG. 9 illustrates a method for encoding a low-level haptic signal in two bands of frequencies according to a second embodiment. Such encoding method corresponds to the signal processing step 212 of FIG. 2 and is for example implemented by an encoder such as the immersive scene generator 111 of FIG. 1. This second method 900 proposes to determine a residual signal corresponding to the difference (i.e., error) between the input signal and a reconstructed version of the low frequency band signal and to encode this residual signal separately, as an additional frequency band, and not within the high frequency band as done in the first method. Any coding method described above may be used to encode the residual signal.

The second method 900 for encoding a low-level haptic signal in two bands of frequencies is for example implemented by an encoder such as the immersive scene generator 111 of FIG. 1. In step 910, the encoder splits the input signal 901 into a low frequency band signal 902 and a high frequency band signal 903 as described above. In step 920, the encoder encodes the low frequency band signal 902 according to one of the signal encoding techniques described above and generates data 907 allowing to reconstruct the low frequency band as described above. The data 907 is then used, in step 930, to determine a reconstructed low frequency band signal 904 using the same technique as available in the decoder on the rendering side. This reconstructed signal 904 is then, in step 940, subtracted from the low frequency band signal 902 to determine a residual signal 905 that represents the low frequency band error. In step 950, this signal 905 is then, in step 950, coded separately from the low and high frequency bands and provided accordingly as additional frequency band data 908. In a first variant of this second embodiment, the encoding of the residual signal is based on wavelets and uses the same technique as for the high frequency band. In step 960, the encoder encodes the high frequency band signal 903 to generate data 909 representing the high frequency band as described above. The data 907, 908 and 909 are then packaged as described above, for example formatted according to the data structure described in FIG. 3 thus allowing to provide these data to a decoder or a haptic rendering device, using either the human-readable interchange file format or a more compact binary format.

The residual band may be added as an additional band to encode the residual signal separately.

In a second variant of the first embodiment, the low frequency band encoding is based on a Curve band encoding so that the step 920 comprises the extraction of keyframes as described above. Any other type of encoding such as the ones described above, or any encoding adapted to a low frequency signal may be used in other variants.

In a third variant of the first embodiment, the high frequency band encoding is based on a Vectorial Wave band encoding so that the step 960 comprises the extraction of wavelets as described above. Any other type of encoding such as the ones described above, or any encoding adapted to a high frequency signal may be used in other variants.

In a fourth variant of this second embodiment, the encoding of the residual band is based on keyframes and uses the same technique as for the low frequency band.

In a fifth variant of this second embodiment, the encoding of the residual band is based on another type of encoding for example based on entropy coding. In such embodiment however, the decoder needs to comprise the corresponding entropy decoding feature and additional data may be encoded to convey some encoding information to the decoder.

This second embodiment has been described here in the context of a decomposition in two frequency bands but its application to context where more than two frequency bands are used is straightforward. Indeed, it's a matter of adding an additional frequency band to the expected set of frequency bands. Indeed, multiple low frequency bands and/or multiple high frequency bands may be used, thus needing a plurality of coding stages 920 and 960 for the different frequency bands but still based on the same principle of using a residual band to encode a residual signal corresponding to the difference between the input signal and a reconstructed version of the low frequency band signal.

In a sixth variant, no high frequency band is used. In this case, the frequency band decomposition of step 910 is a low pass filter that only provides a low frequency band signal 902. No high frequency band needs to be encoded. All the other steps are the same as any variant of the second embodiment.

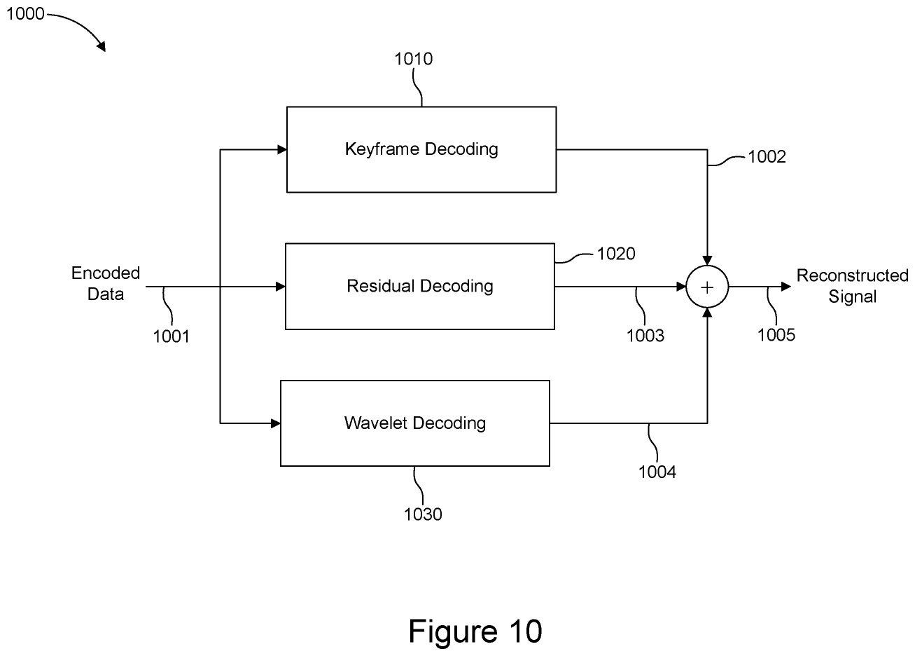

FIG. 10 illustrates a method for decoding a low-level haptic signal in three bands of frequencies according to the first variant of the second embodiment. This method is for example implemented in a haptic rendering device 100 of FIG. 1 and typically executed by the processor 101 of such device. The processor receives encoded data 1001 generated according to FIG. 9, for example formatted according to the data structure described in FIG. 3. In step 1010, the decoder reconstructs the signal 1002 corresponding to the low frequency band signal. In step 1020, the decoder reconstructs the signal 1003 corresponding to residual error signal. In step 1030, the decoder reconstructs the signal 1004 corresponding to the high frequency band signal. By adding these three signals together, the decoder will therefore compensate the coding errors of the low frequency band thanks to the residual error signal 1003 that is carried by the additional frequency band.

In an embodiment, the encoding principle of the first or second method is applied to perform the encoding of an audio signal. Such audio signal may represent any type of audio communication such as a background soundtrack, a sound effect (e.g., explosion) or a voice communication between two users. The audio signal may be part of an immersive scene or can be independent from any immersive scene but using the same format as described in FIG. 3. In addition, an audio signal is sometimes used to render a haptic signal, after a low pass filtering stage. This encoding technique may particularly be interesting for low frequencies such as an audio signal for a subwoofer. All the encoding principles are the same as described above in the context of low-level haptic signals but applied to a more general audio signal or a set of signals (for example: stereo, 5.1 multi-channel audio, etc.). Indeed, a low-level haptic signal is very similar to an audio signal and shares the same characteristics. Such embodiment could therefore be applied to any audio distribution system and the resulting encoded data could be stored on a removable media (for example: memory card, USB stick, hard disk drive, solid-state disk, optical media, etc.) or transmitted over a communication network.

When multiple frequency bands are encoded using keyframes, the principles described in the first or second embodiment are used for each of the frequency bands encoded using keyframes. Resulting residual signals may be encoded separately as different frequency bands or combined together in a single frequency band.

Although embodiments have been described mainly using a decomposition into two frequency bands, the principles of the first and second embodiment easily apply to an application where the decomposition uses more than two frequency bands.

Although different embodiments have been described separately, any combination of the embodiments together can be done while respecting the principles of the disclosure.

Although embodiments are related to haptic effects, the person skilled in the art will appreciate that the same principles could apply to other effects such as the sensorial effects for example and thus would comprise smell, taste, temperature, emotions, intensity highlights, etc. Appropriate syntax would thus determine the appropriate parameters related to these effects.

Reference to “one embodiment” or “an embodiment” or “one implementation” or “an implementation”, as well as other variations thereof, mean that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout the specification are not necessarily all referring to the same embodiment.

Additionally, this application or its claims may refer to “determining” various pieces of information. Determining the information may include one or more of, for example, estimating the information, calculating the information, predicting the information, or retrieving the information from memory.

Additionally, this application or its claims may refer to “obtaining” various pieces of information. Obtaining is, as with “accessing”, intended to be a broad term. Obtaining the information may include one or more of, for example, receiving the information, accessing the information, or retrieving the information (for example, from memory or optical media storage). Further, “obtaining” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

1. A method for encoding comprising,
decomposing an input signal into frequency bands comprising a low frequency band signal and a high frequency band signal;
encoding data extracted from the low frequency band signal;
decoding the encoded data to generate a decoded signal;
determining a residual signal by subtracting the reconstructed decoded signal from the low frequency band signal;
adding the residual signal to the high frequency band signal;
encoding data extracted from the high frequency band signal; and
providing the encoded data for low frequency band and the high frequency band.

2-3. (canceled)

4. The method of claim 1, wherein the encoding of a frequency band uses a transient band encoding and comprises extracting keyframes representing extreme values of the signal and being associated with temporal references, and wherein the reconstruction comprises generating a periodic base signal with an amplitude and a period given by the encoded data.

5. The method of claim 1, wherein the encoding of a frequency band is based on a curve band encoding and comprises extracting keyframes representing extreme values of the signal and being associated to temporal references, and wherein the reconstruction comprises performing an interpolation between keyframes.

6. The method of claim 1, wherein the encoding of a frequency band is based on a vectorial wave band encoding and comprises extracting keyframes defining a temporal reference, an amplitude, and a frequency, and wherein the reconstruction comprises generating a periodic base signal with the amplitude and the period given by the encoded data.

7. The method of claim 1, wherein the encoding of a frequency band uses a wavelet wave encoding and comprises extracting keyframes indicating, for every coefficient of a wavelet transformed and quantized signal, an amplitude value of the wavelet.

8. The method of claim 1, wherein the input signal is a low-level haptic signal.

9. The method of claim 1, wherein the input signal is representative of a tactile or kinesthetic effect.

10. The method of claim 1, wherein the input signal is representative of at least one of smells, tastes, temperatures, emotions and intensity highlights.

11. The method of claim 1, wherein the input signal is an audio signal.

12. A device for encoding comprising a processor configured to:
decompose an input signal into frequency bands comprising a low frequency band signal and a high frequency band signal;
encode data extracted from the low frequency band signal;
decode the encoded data to generate a decoded signal;
determine a residual signal by subtracting the decoded signal from the low frequency band signal;
add the residual signal to the high frequency band signal;
encode data extracted from the high frequency band signal; and
provide the encoded data for low frequency band and the high frequency band.

13-14. (canceled)

15. The device of claim 12, wherein the encoding of a frequency band uses a transient band encoding and comprises extracting keyframes representing extreme values of the signal and being associated to temporal references and wherein the reconstruction comprises generating a periodic base signal with an amplitude and a period given by the encoded data.

16. The method of claim 12, wherein the encoding of a frequency band is based on a curve band encoding and comprises extracting keyframes representing extreme values of the signal and being associated to temporal references and wherein the reconstruction comprises performing an interpolation between keyframes.

17. The method of claim 12, wherein the encoding of a frequency band is based on a vectorial wave band encoding and comprises extracting keyframes defining a temporal reference, an amplitude and a frequency and wherein the reconstruction comprises generating a periodic base signal with the amplitude and the period given by the encoded data.

18. The method of claim 12, wherein the encoding of a frequency band uses a wavelet wave encoding and comprises extracting keyframes indicating, for every coefficient of a wavelet transformed and quantized signal, an amplitude value of the wavelet.

19. The method of claim 12, wherein the input signal is a low-level haptic signal.

20. The method of claim 12, wherein the input signal is representative of a tactile or kinesthetic effect.

21. The method of claim 12, wherein the input signal is representative of smells, tastes, temperatures, emotions, and intensity highlights.

22. The method of claim 12, wherein the input signal is an audio signal.

23. (canceled)

24. A non-transitory computer readable storage medium having stored instructions that, when executed by a processor, cause the processor to:
decompose an input signal into frequency bands comprising a low frequency band signal and a high frequency band signal;
encode data extracted from the low frequency band signal;
decode the encoded data to generate a decoded signal;
determine a residual signal by subtracting the decoded signal from the low frequency band signal;
add the residual signal to the high frequency band signal;
encode data extracted from the high frequency band signal; and
provide the encoded data for low frequency band and the high frequency band.
